(19) United States
(12) Patent Application Publication
(10) Pub. No.: US 2026/0010666 A1
(43) Pub. Date: Jan. 8, 2026

(54) ARCHITECTURAL FLOOR PLAN ESTIMATION

(71) Applicant: Cribsee Inc., San Diego, CA (US)

(72) Inventor: Richard MONTAÑO, San Diego, CA (US)

(21) Appl. No.: 19/127,696

(22) PCT Filed: Nov. 8, 2023
(86) PCT No.: PCT/US2023/037031

§ 371 Date: May 6, 2025

Related U.S. Application Data
(60) Provisional application No. 63/424,034, filed on Nov. 9, 2022.

(51) Int. Cl. G06F 30/13; G06T 7/33; G06T 11/60; G06V 10/82; G06V 20/10

(52) U.S. Cl. CPC G06F 30/13; G06T 7/33; G06T 11/60; G06V 10/82; G06V 20/10

(57) ABSTRACT

A floorplan estimation system includes a server that cooperates with an application running on a user device to generate and provide floor plan estimates for specifically identified properties. The server obtains information about the property and digital media of the property and analyzes the information and digital media to determine a structural footprint for the property that defines a first layer of the overall floorplan estimate. The sever also identifies certain key anchors and key objects associated with the property and analyzes the digital media to determine various structural segments for the property. The various structural segments are stitched together to form a composite floorplan for each level of the property. The composite floorplan for each level defines an additional layer of the overall floorplan estimate. The server combines the floorplan levels together into an overall floorplan estimate for the property.

### BACKGROUND

### Field of the Invention

The present disclosure generally relates to architectural floor plans and is more particularly directed to estimating the architectural floor plan of a structure.

### Related Art

In the real estate industry, conventional property listings typically do not provide floorplans that allow a potential buyer to envision the layout of the property. Consequently, potential buyers must interpret the layout of the property based on an aggregate evaluation of the available property images. This results in properties that are compatible with potential buyers being overlooked. Therefore, what is needed is a system and method that overcomes these problems in the conventional systems as described above.

### SUMMARY

Disclosed herein are systems and methods that address the problems described above. In one aspect, the system includes a server that cooperates with an application running on a user device to generate and provide floor plan estimates for specifically identified properties.

The server obtains available property data including, for example, the location, living area, bedroom count, bathroom count, garage count, number of home levels, room dimensions, key anchors, and key objects. The server also obtains property data including digital media of the property that may include satellite images, photographic images, videos, virtual tours, and other digital representations of the property.

The server analyzes the digital media to determine a structural footprint for the property and to identify certain key anchors and key objects associated with the property. The structural footprint defines a first layer of the overall floorplan estimate.

The server also analyzes the digital media to determine a number of structural segments for the property. The structural segments are stitched together to form a composite floorplan for each level of the property. The composite floorplan for each level defines an additional layer of the overall floorplan estimate.

The server combines the floorplan levels together into an overall floorplan estimate and may subsequently request validation of the estimated floorplan from the property owner or a real estate agent/broker.

Other features and advantages of the present invention will become more readily apparent to those of ordinary skill in the art after reviewing the following detailed description and accompanying drawings.

### BRIEF DESCRIPTION OF THE DRAWINGS

The structure and operation of the present invention will be understood from a review of the following detailed description and the accompanying drawings in which like reference numerals refer to like parts and in which:

FIG. 1 illustrates an example infrastructure, in which one or more of the processes described herein may be implemented, according to an embodiment;

FIG. 2 illustrates an example processing system, by which one or more of the processes described herein may be executed, according to an embodiment;

FIG. 3 illustrates an example training process for an example artificial neural network, by which one or more of the processes described herein may be executed, according to an embodiment;

FIG. 4 illustrates an example operation of an example artificial neural network, by which one or more of the processes described herein may be executed, according to an embodiment;

FIG. 5 is a flow diagram illustrating an example process for estimating a floorplan according to an embodiment of the invention;

FIG. 6 is a flow diagram illustrating an example process for generating a structural footprint outline according to an embodiment of the invention;

FIG. 7 is a block diagram illustrating an example structural footprint outline derived from a satellite image of a property according to an embodiment of the invention;

FIG. 8 is a flow diagram illustrating an example process for generating a floorplan segment according to an embodiment of the invention;

FIGS. 9-12 are block diagrams illustrating an example floorplan segment with anchors according to an embodiment of the invention;

FIG. 13 is a flow diagram illustrating an example process for generating a structural footprint layer with anchors according to an embodiment of the invention;

FIG. 14 is a block diagram illustrating an example structural footprint layer with anchors according to an embodiment of the invention;

FIG. 15 is a flow diagram illustrating an example process for generating a property level layer with anchors according to an embodiment of the invention;

FIG. 16 is a block diagram illustrating an example property level layer with anchors according to an embodiment of the invention; and

FIG. 17-33 are block diagrams illustrating an example system implementation according to an embodiment of the invention.

### DETAILED DESCRIPTION

Disclosed herein are systems, methods, and non-transitory computer-readable media for generating an estimate of the architectural floor plan of a subject property. For example, one method disclosed herein allows for a server to obtain information about a subject property and analyze the information to generate a structural footprint and a plurality of structural segments. The structural segments are aligned to represent one or more levels of the property. The structural footprint and the one or more levels are combined into an overall floorplan for the property.

After reading this description it will become apparent to one skilled in the art how to implement the invention in various alternative embodiments and alternative applications. However, although various embodiments of the present invention will be described herein, it is understood that these embodiments are presented by way of example only, and not limitation. As such, this detailed description of various alternative embodiments should not be construed to limit the scope or breadth of the present invention as set forth in the appended claims.

### 1. System Overview

### 1.1. Infrastructure

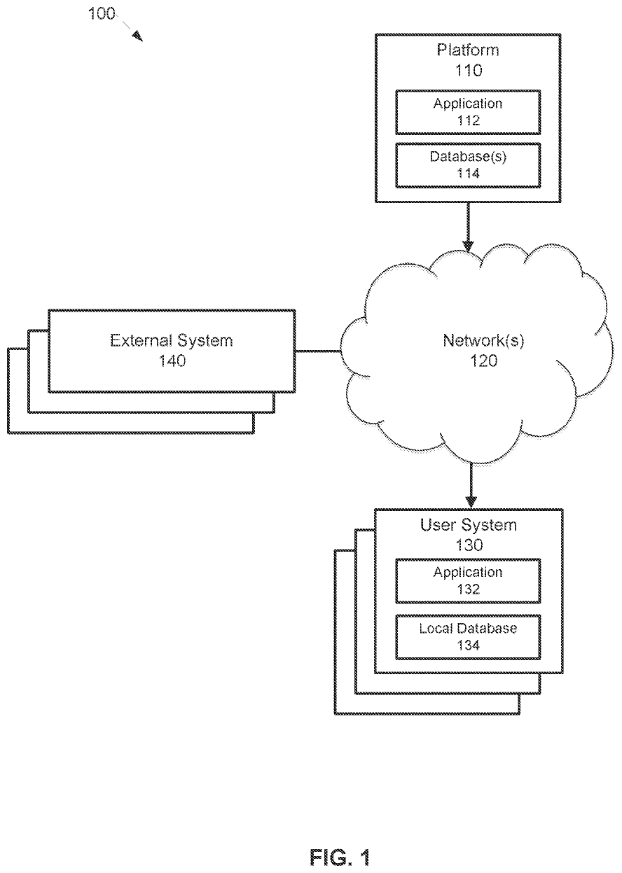

FIG. 1 illustrates an example infrastructure in which one or more of the disclosed processes may be implemented, according to an embodiment. The infrastructure may comprise a platform 110 (e.g., one or more servers) which hosts and/or executes one or more of the various functions, processes, methods, and/or software modules described herein. Platform 110 may comprise dedicated servers, or may instead comprise cloud instances, which utilize shared resources of one or more servers. These servers or cloud instances may be collocated and/or geographically distributed. Platform 110 may also comprise or be communicatively connected to a server application 112 and/or one or more databases 114. In addition, platform 110 may be communicatively connected to one or more user systems 130 via one or more networks 120. Platform 110 may also be communicatively connected to one or more external systems 140 (e.g., other platforms, websites, servers, etc.) via one or more networks 120.

In one aspect, platform 110 embodies a floorplan estimate server that executes application 112 as a software-as-a-service application or as a web portal application. The application 112 obtains property information and stores the information in database 114. The application 112 also analyzes the property information to generate an estimated floorplan for a subject property and to store the estimated floorplan in the database 114.

In one aspect, the application 112 may incorporate artificial intelligence embodied in one or more artificial neural networks to analyze digital media to identify key anchors and key objects within the digital media and to generate individual segments corresponding to an exterior or interior portion of a level of the subject property and to align individual segments using the identified key anchors and key objects to generate a multi-segment exterior or interior portion of a level of the subject property.

Network(s) 120 may comprise the Internet, and platform 110 may communicate with user system(s) 130 through the Internet using standard transmission protocols, such as HyperText Transfer Protocol (HTTP), HTTP Secure (HTTPS), File Transfer Protocol (FTP), FTP Secure (FTPS), Secure Shell FTP (SFTP), and the like, as well as proprietary protocols. While platform 110 is illustrated as being connected to various systems through a single set of network(s) 120, it should be understood that platform 110 may be connected to the various systems via different sets of one or more networks. For example, platform 110 may be connected to a subset of user systems 130 and/or external systems 140 via the Internet, but may be connected to one or more other user systems 130 and/or external systems 140 via an intranet. Furthermore, while only a few user systems 130 and external systems 140, one server application 112, and one set of database(s) 114 are illustrated, it should be understood that the infrastructure may comprise any number of user systems, external systems, server applications, and databases.

User system(s) 130 may comprise any type or types of computing devices capable of wired and/or wireless communication, including without limitation, desktop computers, laptop computers, tablet computers, smart phones or other mobile phones, servers, game consoles, head mounted displays, televisions, set-top boxes, electronic kiosks, point-of-sale terminals, Automated Teller Machines, and/or the like. In one aspect, a user system 130 is a personal mobile device that executes an application 132 that is configured to communicate with the application 112 executing on the platform 110 via the network 120. The application 132 may be configured to provide data and images and video related to the subject property to the application 112 for processing and storage in database 114. The application 132 may also be configured to receive data and images and video related to the subject property from the application 112, for example, the application 132 may receive an estimated floor plan for the subject property from application 112.

External systems 140 may comprise other platforms, websites, servers, and the like. For example, external systems 140 may include third party real estate property listing services such as the Multiple Listing Service, third party satellite imagery services such as Google Earth, and third party image recognition services such as Amazon Rekognition, and other similar third party services that provide information or services upon request. Additionally, external systems 140 may also include third party systems that receive data and information from the platform 110. For example, external systems 140 may include third party real estate services to which the platform 110 provides floor plan estimates for a subject property.

Platform 110 may comprise web servers which host one or more websites and/or web services. In embodiments in which a website is provided, the website may comprise a graphical user interface, including, for example, one or more screens (e.g., webpages) generated in HyperText Markup Language (HTML) or other language. Platform 110 transmits or serves one or more screens of the graphical user interface in response to requests from user system(s) 130. In some embodiments, these screens may be served in the form of a wizard, in which case two or more screens may be served in a sequential manner, and one or more of the sequential screens may depend on an interaction of the user or user system 130 with one or more preceding screens. The requests to platform 110 and the responses from platform 110, including the screens of the graphical user interface, may both be communicated through network(s) 120, which may include the Internet, using standard communication protocols (e.g., HTTP, HTTPS, etc.). These screens (e.g., webpages) may comprise a combination of content and elements, such as text, images, videos, animations, references (e.g., hyperlinks), frames, inputs (e.g., textboxes, text areas, checkboxes, radio buttons, drop-down menus, buttons, forms, etc.), scripts (e.g., JavaScript), and the like, including elements comprising or derived from data stored in one or more databases (e.g., database(s) 114) that are locally and/or remotely accessible to platform 110. Platform 110 may also respond to other requests from user system(s) 130.

Platform 110 may further comprise, be communicatively coupled with, or otherwise have access to one or more database(s) 114. For example, platform 110 may comprise one or more database servers which manage one or more databases 114. A user system 130 or server application 112 executing on platform 110 may submit data (e.g., user data, form data, etc.) to be stored in database(s) 114, and/or request access to data stored in database(s) 114. Any suitable database may be utilized, including without limitation MySQL™, Oracle™, IBM™, Microsoft SQL™, Access™, PostgreSQL™, and the like, including cloud-based databases and proprietary databases. Data may be sent to platform 110, for instance, using the well-known POST request supported by HTTP, via FTP, and/or the like. This data, as well as other requests, may be handled, for example, by server-side web technology, such as a servlet or other software module (e.g., comprised in server application 112), executed by platform 110.

In embodiments in which a web service is provided, platform 110 may receive requests from external system(s) 140, and provide responses in extensible Markup Language (XML), JavaScript Object Notation (JSON), and/or any other suitable or desired format. In such embodiments, platform 110 may provide an application programming interface (API) which defines the manner in which user system(s) 130 and/or external system(s) 140 may interact with the web service. Thus, user system(s) 130 and/or external system(s) 140 (which may themselves be servers), can define their own user interfaces, and rely on the web service to implement or otherwise provide the backend processes, methods, functionality, storage, and/or the like, described herein. For example, in such an embodiment, a client application 132 executing on one or more user system(s) 130 may interact with a server application 112 executing on platform 110 to execute one or more or a portion of one or more of the various functions, processes, methods, and/or software modules described herein. Client application 132 may be “thin,” in which case processing is primarily carried out server-side by server application 112 on platform 110. A basic example of a thin client application 132 is a browser application, which simply requests, receives, and renders webpages at user system(s) 130, while server application 112 on platform 110 is responsible for generating the webpages and managing database functions. Alternatively, the client application may be “thick,” in which case processing is primarily carried out client-side by user system(s) 130. It should be understood that client application 132 may perform an amount of processing, relative to server application 112 on platform 110, at any point along this spectrum between “thin” and “thick,” depending on the design goals of the particular implementation. In any case, the application described herein, which may wholly reside on either platform 110 (e.g., in which case server application 112 performs all processing) or user system(s) 130 (e.g., in which case client application 132 performs all processing) or be distributed between platform 110 and user system(s) 130 (e.g., in which case server application 112 and client application 132 both perform processing), can comprise one or more executable software modules that implement one or more of the processes, methods, or functions of the application described herein.

### 1.2. Example Processing Device

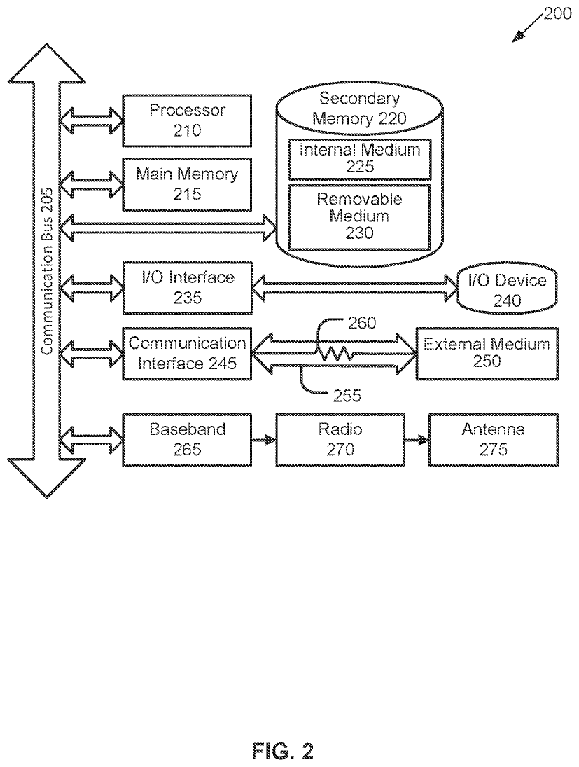

FIG. 2 is a block diagram illustrating an example wired or wireless system 200 that may be used in connection with various embodiments described herein. For example, system 200 may be used as or in conjunction with one or more of the functions, processes, or methods (e.g., to store and/or execute the application or one or more software modules of the application) described herein, and may represent components of platform 110, user system(s) 130, external system(s) 140, and/or other processing devices described herein. System 200 can be a server or any conventional personal computer, or any other processor-enabled device that is capable of wired or wireless data communication. Other computer systems and/or architectures may be also used, as will be clear to those skilled in the art.

System 200 preferably includes one or more processors, such as processor 210. Additional processors may be provided, such as an auxiliary processor to manage input/output, an auxiliary processor to perform floating-point mathematical operations, a special-purpose microprocessor having an architecture suitable for fast execution of signal-processing algorithms (e.g., digital-signal processor), a slave processor subordinate to the main processing system (e.g., back-end processor), an additional microprocessor or controller for dual or multiple processor systems, and/or a coprocessor. Such auxiliary processors may be discrete processors or may be integrated with processor 210. Examples of processors which may be used with system 200 include, without limitation, the Pentium® processor, Core i7® processor, and Xeon® processor, all of which are available from Intel Corporation of Santa Clara, California.

Processor 210 is preferably connected to a communication bus 205. Communication bus 205 may include a data channel for facilitating information transfer between storage and other peripheral components of system 200. Furthermore, communication bus 205 may provide a set of signals used for communication with processor 210, including a data bus, address bus, and/or control bus (not shown). Communication bus 205 may comprise any standard or non-standard bus architecture such as, for example, bus architectures compliant with industry standard architecture (ISA), extended industry standard architecture (EISA), Micro Channel Architecture (MCA), peripheral component interconnect (PCI) local bus, standards promulgated by the Institute of Electrical and Electronics Engineers (IEEE) including IEEE 488 general-purpose interface bus (GPIB), IEEE 696/S-100, and/or the like.

System 200 preferably includes a main memory 215 and may also include a secondary memory 220. Main memory 215 provides storage of instructions and data for programs executing on processor 210, such as one or more of the functions and/or modules discussed herein. It should be understood that programs stored in the memory and executed by processor 210 may be written and/or compiled according to any suitable language, including without limitation C/C++, Java, JavaScript, Perl, Visual Basic, .NET, and the like. Main memory 215 is typically semiconductor-based memory such as dynamic random access memory (DRAM) and/or static random access memory (SRAM). Other semiconductor-based memory types include, for example, synchronous dynamic random access memory (SDRAM), Rambus dynamic random access memory (RDRAM), ferroelectric random access memory (FRAM), and the like, including read only memory (ROM).

Secondary memory 220 may optionally include an internal medium 225 and/or a removable medium 230. Removable medium 230 is read from and/or written to in any well-known manner. Removable storage medium 230 may be, for example, a magnetic tape drive, a compact disc (CD) drive, a digital versatile disc (DVD) drive, other optical drive, a flash memory drive, and/or the like.

Secondary memory 220 is a non-transitory computer-readable medium having computer-executable code (e.g., disclosed software modules) and/or other data stored thereon. The computer software or data stored on secondary memory 220 is read into main memory 215 for execution by processor 210.

In alternative embodiments, secondary memory 220 may include other similar means for allowing computer programs or other data or instructions to be loaded into system 200. Such means may include, for example, a communication interface 245, which allows software and data to be transferred from external storage medium 250 to system 200. Examples of external storage medium 250 may include an external hard disk drive, an external optical drive, an external magneto-optical drive, and/or the like. Other examples of secondary memory 220 may include semiconductor-based memory, such as programmable read-only memory (PROM), erasable programmable read-only memory (EPROM), electrically erasable read-only memory (EEPROM), and flash memory (block-oriented memory similar to EEPROM).

As mentioned above, system 200 may include a communication interface 245. Communication interface 245 allows software and data to be transferred between system 200 and external devices (e.g. printers), networks, or other information sources. For example, computer software or executable code may be transferred to system 200 from a network server (e.g., platform 110) via communication interface 245. Examples of communication interface 245 include a built-in network adapter, network interface card (NIC), Personal Computer Memory Card International Association (PCMCIA) network card, card bus network adapter, wireless network adapter, Universal Serial Bus (USB) network adapter, modem, a wireless data card, a communications port, an infrared interface, an IEEE 1394 fire-wire, and any other device capable of interfacing system 200 with a network (e.g., network(s) 120) or another computing device. Communication interface 245 preferably implements industry-promulgated protocol standards, such as Ethernet IEEE 802 standards, Fiber Channel, digital subscriber line (DSL), asynchronous digital subscriber line (ADSL), frame relay, asynchronous transfer mode (ATM), integrated digital services network (ISDN), personal communications services (PCS), transmission control protocol/Internet protocol (TCP/IP), serial line Internet protocol/point to point protocol (SLIP/PPP), and so on, but may also implement customized or non-standard interface protocols as well.

Software and data transferred via communication interface 245 are generally in the form of electrical communication signals 260. These signals 260 may be provided to communication interface 245 via a communication channel 255. In an embodiment, communication channel 255 may be a wired or wireless network (e.g., network(s) 120), or any variety of other communication links. Communication channel 255 carries signals 260 and can be implemented using a variety of wired or wireless communication means including wire or cable, fiber optics, conventional phone line, cellular phone link, wireless data communication link, radio frequency (“RF”) link, or infrared link, just to name a few.

Computer-executable code (e.g., computer programs, such as the disclosed application, or software modules) is stored in main memory 215 and/or secondary memory 220. Computer programs can also be received via communication interface 245 and stored in main memory 215 and/or secondary memory 220. Such computer programs, when executed, enable system 200 to perform the various functions of the disclosed embodiments as described elsewhere herein.

In this description, the term “computer-readable medium” is used to refer to any non-transitory computer-readable storage media used to provide computer-executable code and/or other data to or within system 200. Examples of such media include main memory 215, secondary memory 220 (including internal memory 225, removable medium 230, and external storage medium 250), and any peripheral device communicatively coupled with communication interface 245 (including a network information server or other network device). These non-transitory computer-readable media are means for providing executable code, programming instructions, software, and/or other data to system 200.

In an embodiment that is implemented using software, the software may be stored on a computer-readable medium and loaded into system 200 by way of removable medium 230, I/O interface 235, or communication interface 245. In such an embodiment, the software is loaded into system 200 in the form of electrical communication signals 260. The software, when executed by processor 210, preferably causes processor 210 to perform one or more of the processes and functions described elsewhere herein.

In an embodiment, I/O interface 235 provides an interface between one or more components of system 200 and one or more input and/or output devices 240. Example input devices include, without limitation, sensors, keyboards, touch screens or other touch-sensitive devices, biometric sensing devices, computer mice, trackballs, pen-based pointing devices, and/or the like. Examples of output devices include, without limitation, other processing devices, cathode ray tubes (CRTs), plasma displays, light-emitting diode (LED) displays, liquid crystal displays (LCDs), printers, vacuum fluorescent displays (VFDs), surface-conduction electron-emitter displays (SEDs), field emission displays (FEDs), head mounted displays (HMDs), and/or the like. In some cases, an input and output device 240 may be combined, such as in the case of a touch panel display (e.g., in a smartphone, tablet, or other mobile device).

In an embodiment, the I/O device 240 may be any type of external or integrated display and may include one or more discrete displays that in aggregate form the I/O device 240. The I/O device 240 may be capable of 2D or 3D presentation of visual information to a user of the system 200. In one embodiment, the I/O device 240 may be a virtual reality or augmented reality device in the form of HMD by the user so the user may visualize the presentation of information in 3D.

System 200 may also include optional wireless communication components that facilitate wireless communication over a voice network and/or a data network (e.g., in the case of user system 130). The wireless communication components comprise an antenna system 275, a radio system 270, and a baseband system 265. In system 200, radio frequency (RF) signals are transmitted and received over the air by antenna system 275 under the management of radio system 270.

In an embodiment, antenna system 275 may comprise one or more antennae and one or more multiplexors (not shown) that perform a switching function to provide antenna system 275 with transmit and receive signal paths. In the receive path, received RF signals can be coupled from a multiplexor to a low noise amplifier (not shown) that amplifies the received RF signal and sends the amplified signal to radio system 270.

In an alternative embodiment, radio system 270 may comprise one or more radios that are configured to communicate over various frequencies. In an embodiment, radio system 270 may combine a demodulator (not shown) and modulator (not shown) in one integrated circuit (IC). The demodulator and modulator can also be separate components. In the incoming path, the demodulator strips away the RF carrier signal leaving a baseband receive audio signal, which is sent from radio system 270 to baseband system 265.

If the received signal contains audio information, then baseband system 265 decodes the signal and converts it to an analog signal. Then the signal is amplified and sent to a speaker. Baseband system 265 also receives analog audio signals from a microphone. These analog audio signals are converted to digital signals and encoded by baseband system 265. Baseband system 265 also encodes the digital signals for transmission and generates a baseband transmit audio signal that is routed to the modulator portion of radio system 270. The modulator mixes the baseband transmit audio signal with an RF carrier signal, generating an RF transmit signal that is routed to antenna system 275 and may pass through a power amplifier (not shown). The power amplifier amplifies the RF transmit signal and routes it to antenna system 275, where the signal is switched to the antenna port for transmission.

Baseband system 265 is also communicatively coupled with processor 210, which may be a central processing unit (CPU). Processor 210 has access to data storage areas 215 and 220. Processor 210 is preferably configured to execute instructions (i.e., computer programs, such as the disclosed application, or software modules) that can be stored in main memory 215 or secondary memory 220. Computer programs can also be received from baseband processor 260 and stored in main memory 210 or in secondary memory 220, or executed upon receipt. Such computer programs, when executed, enable system 200 to perform the various functions of the disclosed embodiments.

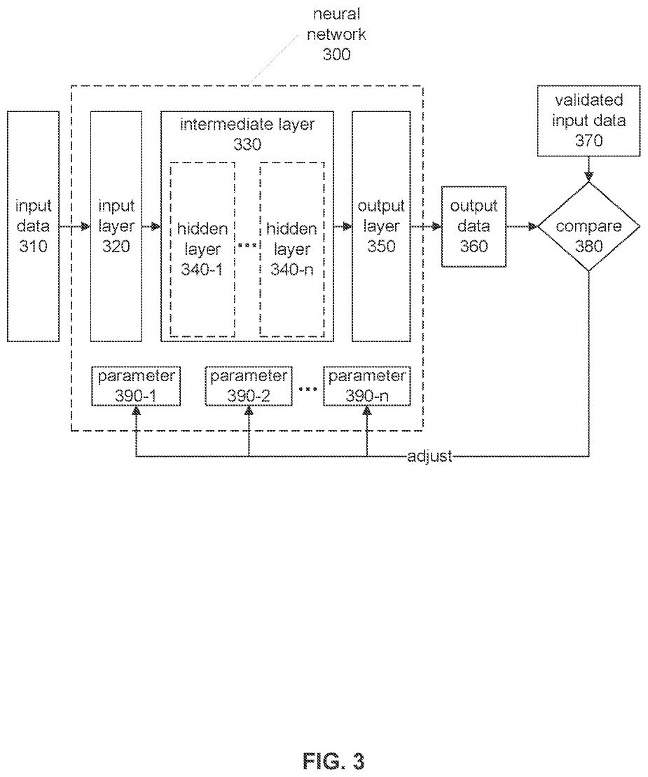

FIG. 3 illustrates an example training process for an example artificial neural network (ANN) 300, by which one or more of the processes described herein may be executed, according to an embodiment. In the illustrated embodiment, the ANN 300 receives input data 310 at the input layer 320. The input layer 320 processes the input data to generate one or more outputs that are provided to the intermediate layer 330. As the input layer 320 processes the input data 310, the input layer 320 may use one or more parameters 390 (390-1, 390-2, . . . , 390-n) in the processing.

The intermediate layer 330 may comprise a plurality of hidden layers 340 (340-1, . . . , 340-n). Each hidden layer 340 of the intermediate layer 330 receives one or more inputs from the input layer 320 or another hidden layer 340 and processes the one or more inputs to generate one or more outputs that are provided to another hidden layer 340 or to the output layer 350. The output layer 350 processes all of the inputs it receives from the various hidden layers 340 of the intermediate layer 330 and generates output data 360. The output data 360 is compared to validated input data 370 and the results of the comparison 380 are used to adjust one or more parameters 390. Advantageously, the adjusted parameters 390 operate to improve the subsequent processing of input data 310 by the ANN 300 to generate more accurate output data 360.

In one aspect, known images of key anchors (e.g., chimney, skylight, plumbing vents, fireplace, doors, windows, driveway, swimming pool, hot tub, microwave, stove, sink, refrigerator, corners, and other semi-permanent parts of the physical structure or property) and key objects (e.g., vehicles, televisions, furniture, art, and other easily movable items in the structure or on the property) are fed into the ANN 300 to train the ANN to identify patterns in the images that correspond to such key anchors and key objects. Additionally, known images of floorplans are also fed into the ANN 300 to train the ANN to identify a floorplan, for example from a sketch or other type of digital media.

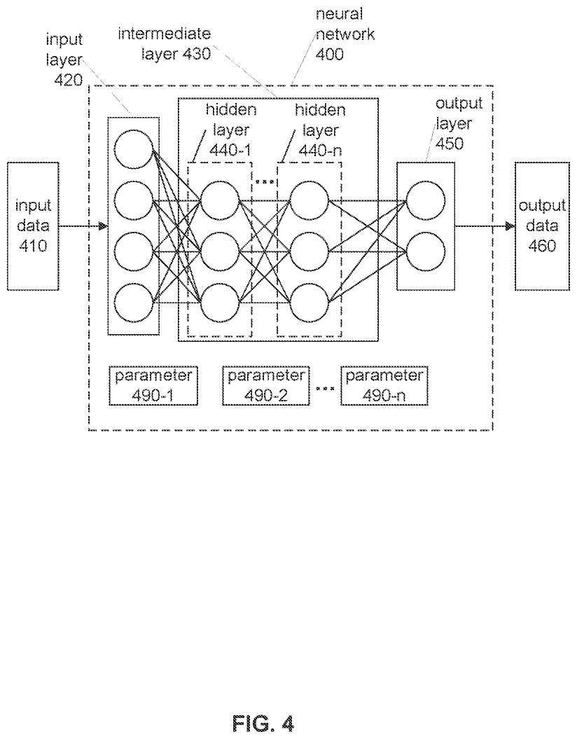

FIG. 4 illustrates an example operation of an example artificial neural network 400, by which one or more of the processes described herein may be executed, according to an embodiment. In the illustrated embodiment, the ANN 400 receives input data 410 at the input layer 420. The input layer 420 processes the input data to generate one or more outputs that are provided to the intermediate layer 430. As the input layer 420 processes the input data 410, the input layer 420 may use one or more parameters 490 (490-1, 490-2, . . . , 490-n) in the processing.

The intermediate layer 430 may comprise a plurality of hidden layers 440 (440-1, . . . , 440-n). Each hidden layer 440 of the intermediate layer 430 receives one or more inputs from the input layer 420 or another hidden layer 440 and processes the one or more inputs to generate one or more outputs that are provided to another hidden layer 440 or to the output layer 450. As each hidden layer 440 performs its processing, the respective hidden layer 440 may use one or more parameters 490 (490-1, 490-2, . . . , 490-n) in the processing. The output layer 450 processes all of the inputs it receives from the various hidden layers 440 of the intermediate layer 430 and generates output data 460.

In one aspect, digital media of the subject property may be processed by one or more ANNs 400 to identify key anchors and key objects that appear in photos and satellite images of the subject property. One or more ANNs 400 may also be used to generate an estimated structural footprint of the subject property using photos and satellite images of the subject property. In one aspect, an estimated structural footprint of the subject property defines a layer in the final estimated floorplan.

Additionally, one or more ANNs 400 may also be used to generate individual exterior or interior segments of the estimated floorplan corresponding to an exterior or interior portion of a level of the subject property. One or more ANNs 400 may also be used to align individual exterior and/or interior segments of the estimated floorplan using the identified key anchors and key objects to generate an exterior or interior portion of a level or a complete level of the subject property. In one aspect, an estimated floor plan of a complete level of the subject property defines a layer in the final estimated floorplan.

Moreover, one or more ANNs 400 may also be used to combine one or more estimated floor plan layers into an estimated floorplan for the subject property. Advantageously, the estimated floorplan for the subject property may include various room identifiers and dimensions and may also include identifiers for various key anchors and key objects.

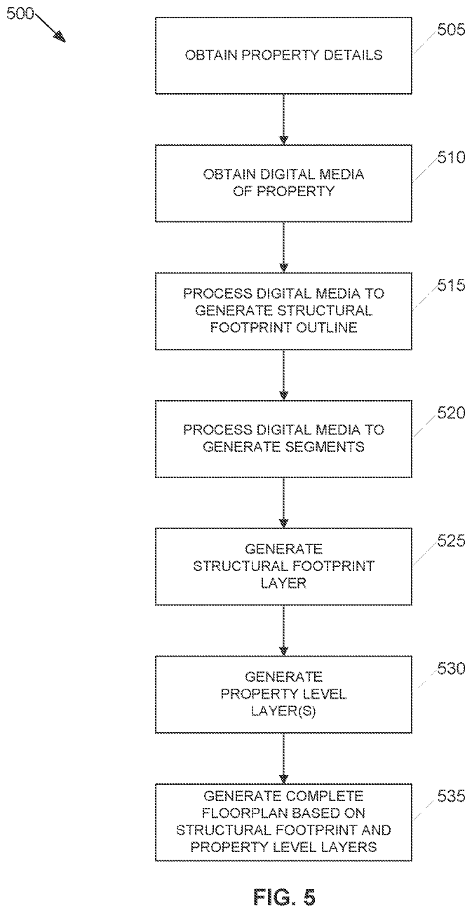

FIG. 5 is a flow diagram illustrating an example process 500 for estimating a floorplan according to an embodiment of the invention. In one aspect, the illustrated process may be carried out by the system described with respect to FIG. 1 in combination with one of more processing devices described with respect to FIG. 2 that may be executing artificial neural networks that are trained and operated as described in FIGS. 3 and 4.

Initially, at 505 the system obtains detailed information about the subject property. Those details may include the location of the subject property (e.g., the address, a geocode, GPS coordinates, latitude-longitude coordinates, and the like), the living area of the property (e.g., in square feet or square meters), the number of bedrooms, number of bathrooms, number of garages, number of levels, dimensions for each room (e.g., in square feet or square meters), identification of key anchors, identification of key objects, and other information about the subject property. Examples of key anchors include chimneys, skylights, plumbing vents, fireplaces, doors, windows, driveways, swimming pools, hot tubs, microwaves, stoves, sinks, refrigerators, and other semi-permanent parts of the physical structure or parcel of the subject property. Examples of key objects include vehicles, televisions, furniture, art, and other movable items in the physical structure or on the parcel of the subject property.

Next, at 510 the system obtains digital media corresponding to the subject property. The digital media may be obtained from an external system or third party system such as the MLS service or Google Earth and the like. Digital media corresponding to the subject property may include photos of the property, exterior and interior photos of the physical structure(s) on the property, satellite images of the property, videos of the property, virtual tours of the property, and other digital representations of the property and/or physical structures on the property. Other digital representations may include architectural reliefs of the exterior of the structures, sketches of the structures and/or floorplans, building plans for renovations or additions to the subject property, and the like.

Next, at 515 the system analyzes the digital media to generate an outline of the structural footprint of the subject property. In one aspect, the outline of the structural footprint is derived from satellite images of the subject property and defines the perimeter of the floorplan for the subject property.

Next, at 520 the system analyzes the digital media to generate floorplan segments of the subject property. In one aspect, the outline of the structural footprint is derived from satellite images of the subject property and defines the perimeter of the floorplan for the subject property. In one aspect, each photo of the subject property is analyzed to generate a floorplan segment of the subject property and the various segments are correlated to each other and to the structural outline.

Next, at 525 the system generates an estimated structural footprint layer for the subject property based on the correlation of the exterior segments and the interior segments and the structural outline. The estimated structural footprint layer of the subject property defines a layer in the complete estimated floorplan of the subject property.

Next, at 530 the system generates an estimated floorplan layout for each level of the subject property based on the correlation of the exterior segments and the interior segments and the structural outline. For example, one level may be the basement and one level may be the ground floor and one level may be the upstairs for a multilevel subject property. The estimated floorplan layout for each level defines a respective layer in the complete estimated floorplan of the subject property.

Finally, at 535 the system combines the various layers that were generated for the structural footprint and the one or more levels of the subject property to generate the complete floorplan for the subject property.

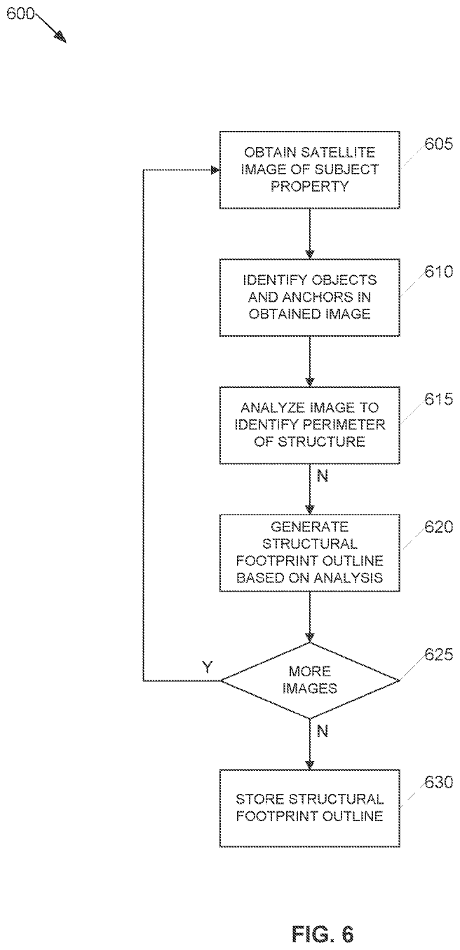

FIG. 6 is a flow diagram illustrating an example process 600 for generating a structural footprint outline according to an embodiment of the invention. In one aspect, the illustrated process may be carried out by the system described with respect to FIG. 1 in combination with one of more processing devices described with respect to FIG. 2 that may be executing artificial neural networks that are trained and operated as described in FIGS. 3 and 4.

Initially, at 605 the system obtains a satellite image of a subject property. The satellite image may be obtained from a data storage area or from an external system or third party system such as Google Earth and the like.

Next, at 610 the system analyzes the image to identify objects and anchors that appear in the image. Such objects and anchors in a satellite image may include, for example, roofs of structures, perimeter corners of roofs, solar panels, chimneys, skylights, plumbing vents, driveways, vehicles, yards, swimming pools, hot tubs, sidewalks, pathways, outdoor kitchens, and the like.

Next, at 615 the system analyzes the image and the various identified objects and anchors to identify a perimeter of the structure. In one aspect, the roofline of the property provides an initial starting point to identify the perimeter of the structure.

Next, at 620, the system generates a structural footprint outline based on the analysis. In one aspect, a structural footprint outline is a two dimensional representation of the perimeter of the subject property in the satellite image. For example, a structural footprint outline can be an enclosed polygonal shape that approximates the relative locations and lengths of the exterior walls of the subject property in the satellite image. Additionally, when the structural footprint outline is generated, the system adjusts the relative lengths of the perimeter portions of the outline based on the details of the subject property such as the living area, room dimensions, and the like. One aspect of the structural footprint outline is the identification of certain anchors in the outline. For example, the outline will have certain corners or angles that are included and some or all of these corners and angles can be identified as anchors on the structural footprint outline.

Next, if there are more satellite images of the subject property to analyze as determined at 625, the system obtains the subsequent satellite image of the subject property and performs the same steps through 615 and then at 620, the system augments and/or updates the existing structural footprint outline based on the analysis of the subsequent satellite image. In this fashion, the system may analyze a plurality of satellite images of the subject property to generate the structural footprint outline based on a variety of perspectives.

Finally, at 630 the system stores the structural footprint outline in a data storage area.

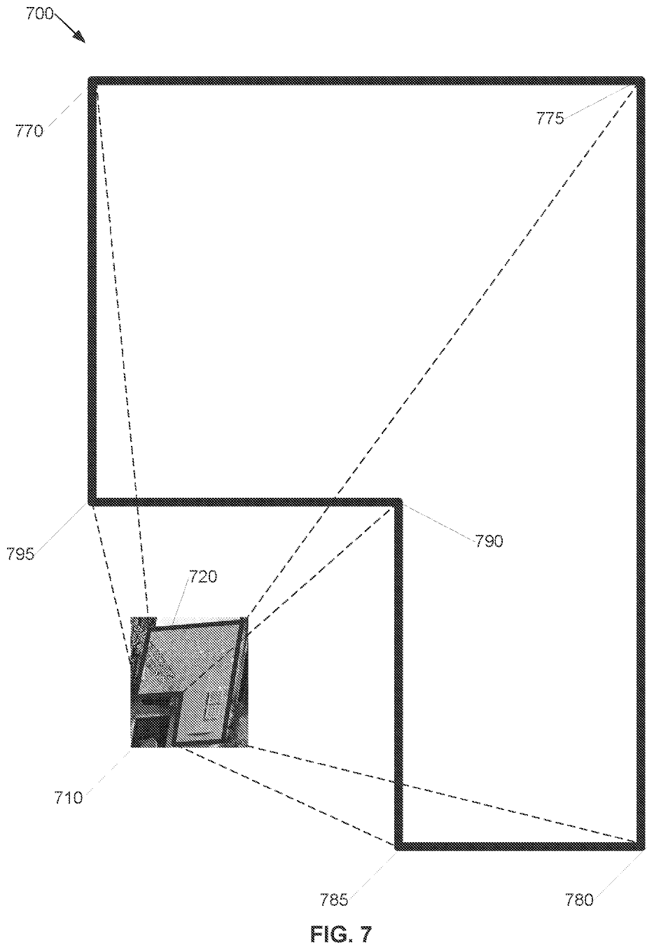

FIG. 7 is a block diagram illustrating an example structural footprint outline 700 derived from a satellite image 710 of a subject property according to an embodiment of the invention. In the illustrated embodiment, the structural footprint outline 700 is derived from an outline 720 of the roofline of the structure in the satellite image 710 of the subject property. Additionally, in the illustrated embodiment a plurality of anchors are included at corners/angles 770, 775, 780, 785, 790, 795 of the structural footprint outline 700.

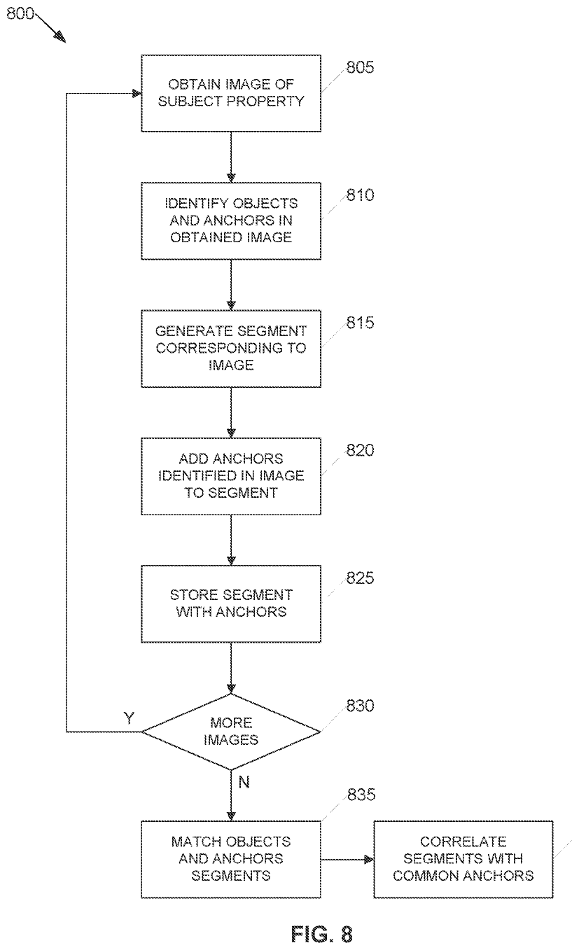

FIG. 8 is a flow diagram illustrating an example process 800 for generating a floorplan segment according to an embodiment of the invention. In one aspect, the illustrated process may be carried out by the system described with respect to FIG. 1 in combination with one of more processing devices described with respect to FIG. 2 that may be executing artificial neural networks that are trained and operated as described in FIGS. 3 and 4.

Initially, at 805, the system obtains an image of a subject property. The property image may be obtained from a data storage area or from an external system or third party system such as the MLS and the like. The image of the subject property may be an image of a portion of the exterior of the property or an image of a portion of the interior of the property.

Next, at 810, the system analyzes the image to identify objects and anchors that appear in the image. Such objects and anchors in an image of an exterior portion or an interior portion of the subject property may include, for example, doors, windows, passage ways, wall corners, fireplaces, appliances such as refrigerators, dishwashers, stoves, ovens, microwaves, clothes washing machine, clothes drying machine, closets, sinks, toilets, showers, bathtubs, countertops, built-in shelving, staircases, television, furniture, art, and the like.

Next, at 815, the system generates a segment corresponding to the image of the subject property. In one aspect, a segment is a two dimensional representation of a portion of the floorplan of the subject property that is captured in the image. Advantageously, each image of the subject property generates a single segment.

Next, at 820, the system adds the anchors that were identified in the corresponding image corresponding to the segment. Advantageously, each anchor is positioned relative to other anchors in accordance with the positioning in the corresponding image. In one aspect, relative measurements may be estimated by the system, for example, the distance between a corner and a window or the distance between and window and a door. Although the final scale of the overall floorplan may not be established at the time when a segment is generated, the relative scale of a segment can subsequently be translated to the final scale in order accurately position each anchor in the overall floorplan. In addition to adding anchors to the segment, the system may also add objects to the segment. Although the relative positioning of objects is more likely to change, the inclusion of objects in the segment may facilitate matching and correlating of segments.

Next, at 825, the system stores the segment with the included anchors.

Next, if there are more images of the subject property to analyze as determined at 830, the system obtains the subsequent image at 805 and processes the image as described above to store each subsequent segment.

Next, at 835, the system analyzes all of the segments and matches objects and anchors that appear in each segment with the objects and anchors that appear in each other segment.

Next, at 840, segments with matching anchors and/or objects can be correlated together by the system to generate a linked list that correlates all of the various segments to each other directly or indirectly via other segments.

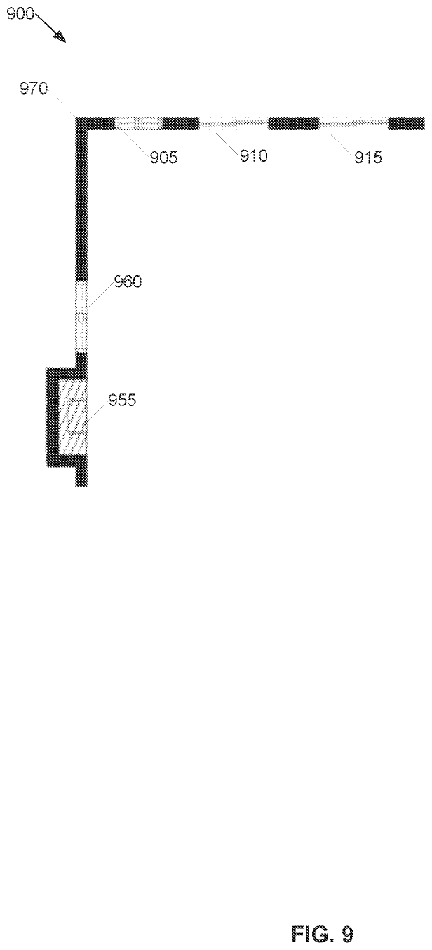

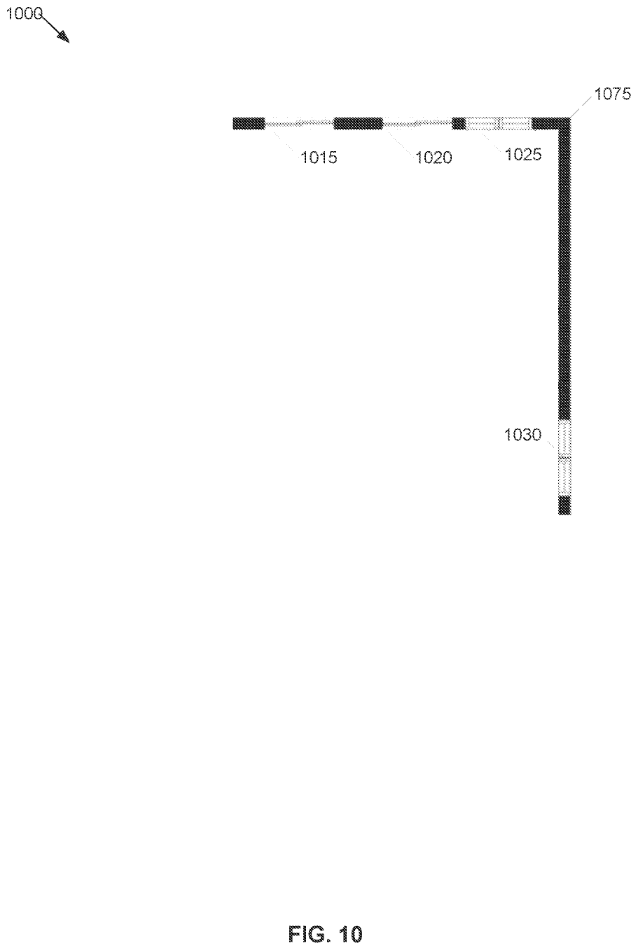

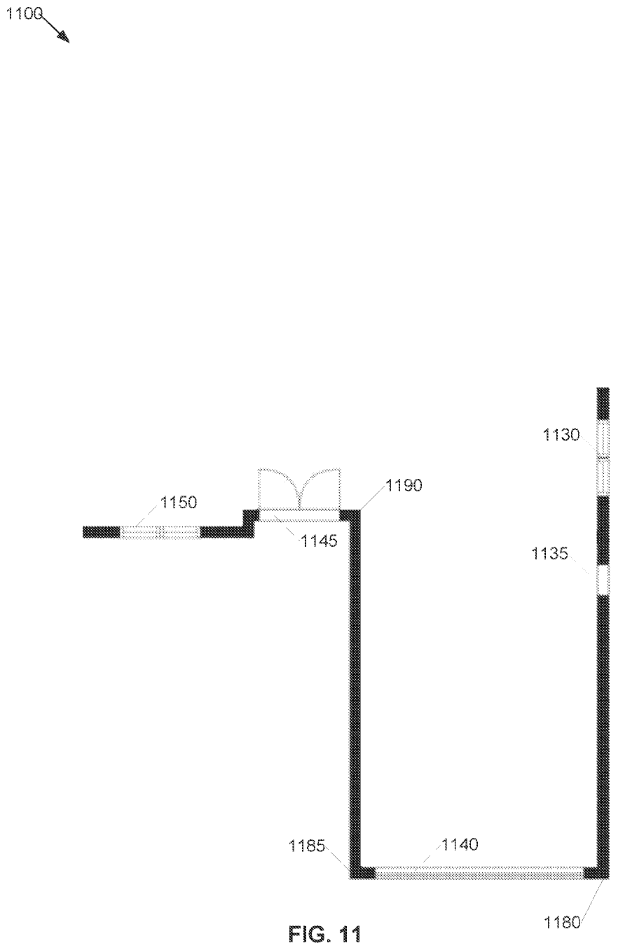

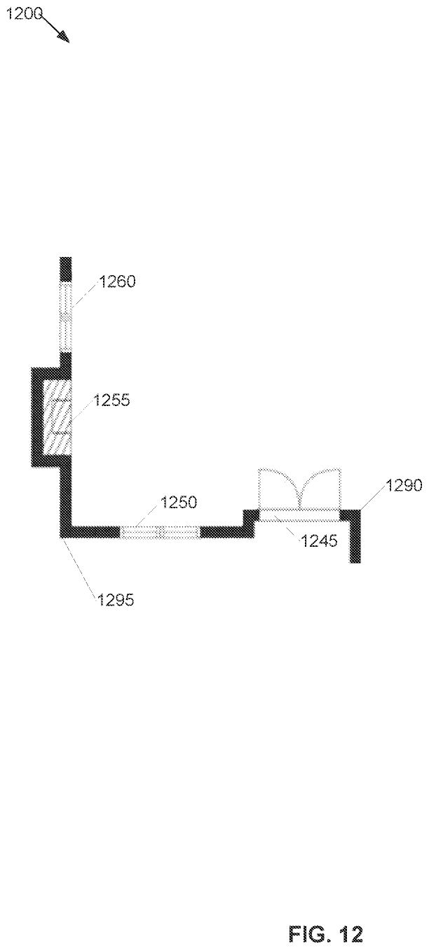

FIGS. 9-12 are block diagrams illustrating example floorplan segments 900, 1000, 1100, and 1200 according to an embodiment of the invention. In the illustrated embodiments, the various floorplan segments 900, 1000, 1100, and 1200 include anchors 905, 910, 915, 955, 960, 1015, 1020, 1025, 1030, 1130, 1135, 1140, 1145, 1150, 1245, 1250, 1255, and 1260. Common anchors that appear in two or more segments includes 915/1015, 955/1255, 960/1260, 1030/1130, 1145/1245, 1190/1290. Advantageously, each segment includes at least one common anchor that appears in another segment. Additionally, the corner/angle anchors that are included in the structural footprint outline are also included in one or more of the floorplan segments 900, 1000, 1100, and 1200. These common anchors advantageously correlate the various floorplan segments 900, 1000, 1100, and 1200 to the structural footprint outline.

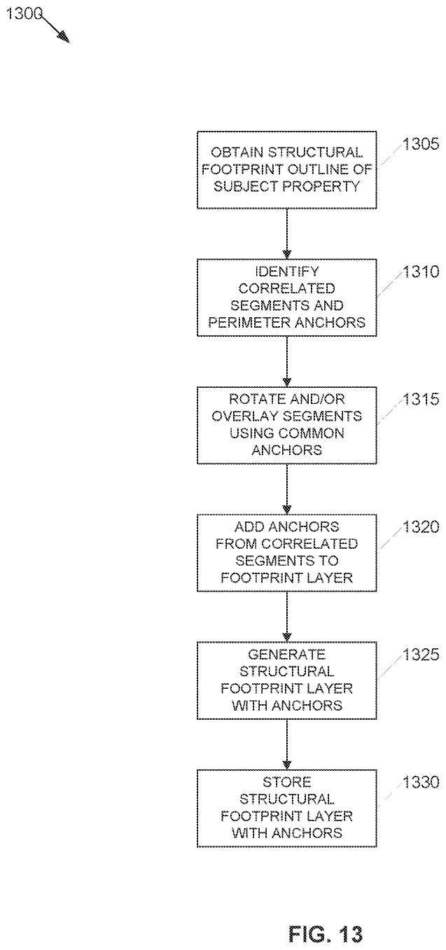

FIG. 13 is a flow diagram illustrating an example process 1300 for generating a structural footprint layer with anchors according to an embodiment of the invention. In one aspect, the illustrated process may be carried out by the system described with respect to FIG. 1 in combination with one of more processing devices described with respect to FIG. 2 that may be executing artificial neural networks that are trained and operated as described in FIGS. 3 and 4.

Initially, at 1305 the system obtains the structural footprint outline of the subject property. Advantageously, the structural footprint outline includes one or more anchors. For example, the structural footprint outline may include anchors at one or more corners/angles of the outline.

Next, at 1310 the system identifies correlated segments and their corresponding perimeter anchors. In one aspect, the system identifies a segment having a corner/angle anchor and corresponds to a corner/angle anchor in the structural footprint outline. Advantageously, once the first segment having an anchor that correlates to an anchor in the structural footprint outline is identified, all of the remaining segments are known to be correlated to the first segment, as previously described with respect to FIG. 8.

Next, at 1315 the system rotates and/or overlays the first segment onto the structural footprint outline by matching the common anchor. The system then proceeds to rotate and/or overlay each additional segment based on common anchors between the segments. Additionally, as each segment is rotated and/or overlayed onto the structural footprint outline, eventually an additional common anchor (e.g., corner/angle) between the structural footprint outline and a segment will be encountered and the system can adjust the relative lengths of the perimeter walls and the distances between anchors such as the corners/angles and doors and windows, etc. Additional segments are added until the entire structural footprint outline has been overlayed by a segment and the structural footprint outline an the combined segments have been aligned.

Next, at 1320 the system adds each of the anchors from the overlayed segments to the structural footprint outline at their respective positions. In one aspect, the relative scales between various segments and the structural footprint outline are harmonized when the anchors from the various segments are added to the structural footprint outline.

Next, at 1325 the system generates the structural footprint layer of the overall floorplan with the anchors. Advantageously, the structural footprint layer is a two dimensional representation of the perimeter of the overall floorplan that also includes the anchors.

Next, at 1330 the system stores the structural footprint layer with the anchors in a data storage area.

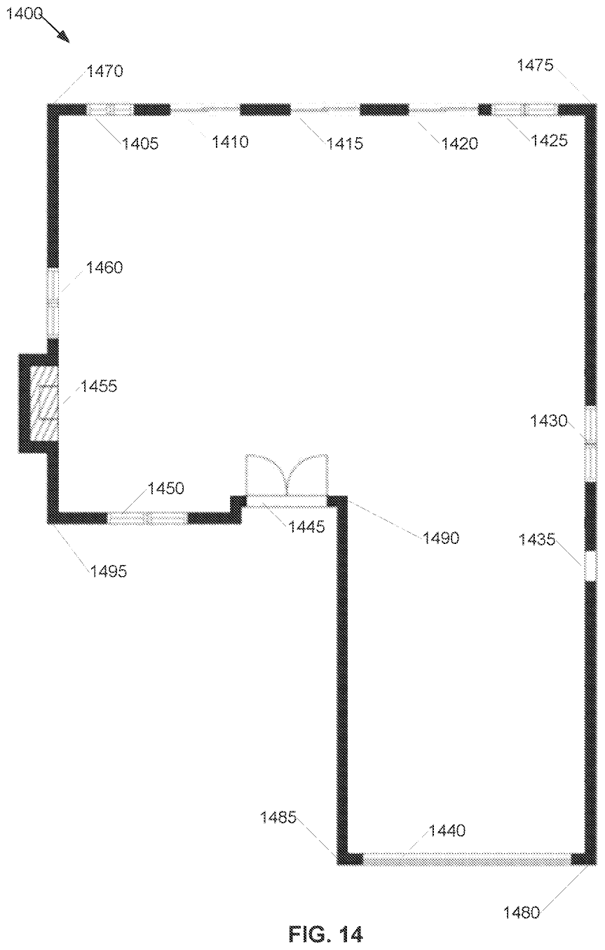

FIG. 14 is a block diagram illustrating an example structural footprint layer 1400 according to an embodiment of the invention. In the illustrated embodiment, the structural footprint layer 1400 includes anchors 1405, 1410, 1415, 1420, 1425, 1430, 1435, 1440, 1445, 1450, 1455, 1460, as well as the corner/angle anchors 1470, 1475, 1480, 1485, 1490, and 1495.

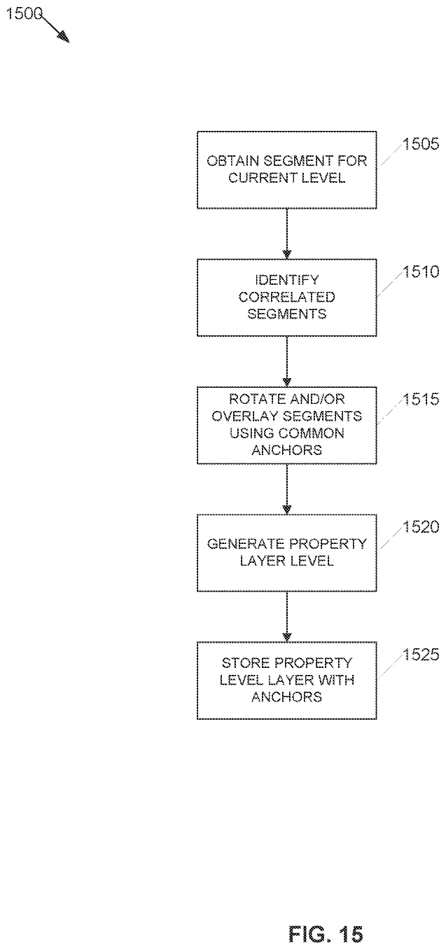

FIG. 15 is a flow diagram illustrating an example process 1500 for generating a property level layer with anchors according to an embodiment of the invention. In one aspect, the illustrated process may be carried out by the system described with respect to FIG. 1 in combination with one of more processing devices described with respect to FIG. 2 that may be executing artificial neural networks that are trained and operated as described in FIGS. 3 and 4.

Initially, at 1505 the system obtains a first segment for a current level of the subject property. Advantageously, the first segment includes one or more anchors. For example, the first segment may include a corner/angle anchor or a window or a door or some other type of anchor.

Next, at 1510 the system identifies segments that are correlated to the first segment. As previously described with respect to FIG. 8, the first segment is directly or indirectly connected to each other segment for the current level by way of their respective common anchors. For example, the system identifies the first segment having a first anchor that correlates to the same first anchor in a second segment. Advantageously, once the first segment having an anchor that correlates to an anchor in the second segment is identified, all of the remaining segments for the current level are then known by way of their correlation to other segments.

Next, at 1515 the system rotates and/or overlays the first segment and the second segment by matching the common anchor(s). The system then proceeds to rotate and/or overlay each additional segment based on common anchors between the segments. Additionally, as each segment is rotated and/or overlayed onto an adjacent segment, eventually a common anchor (e.g., corner/angle) between the structural footprint outline and a segment will be encountered. The system can then advantageously adjust the relative lengths of the perimeter walls and the distances between anchors such as the corners/angles and doors and windows, etc. The system continues to add segments for the current level until a floorplan for the entire level has been generated, including the exterior/perimeter portions and the interior portions, and the combined segments for the property level layer have been aligned with the structural footprint layer. In one aspect, the relative scales between various segments are harmonized when the anchors from the property level layer are used to align the property level layer with the structural footprint layer.

Next, at 1520 the system generates the property level layer of the overall floorplan with the anchors. Advantageously, the property level layer is a two dimensional representation of the overall floorplan that includes various anchors. The property level can be, for example, the basement, the main floor, the upstairs, or some other level within the structure.

Next, at 1525 the system stores the property level layer with the anchors in a data storage area.

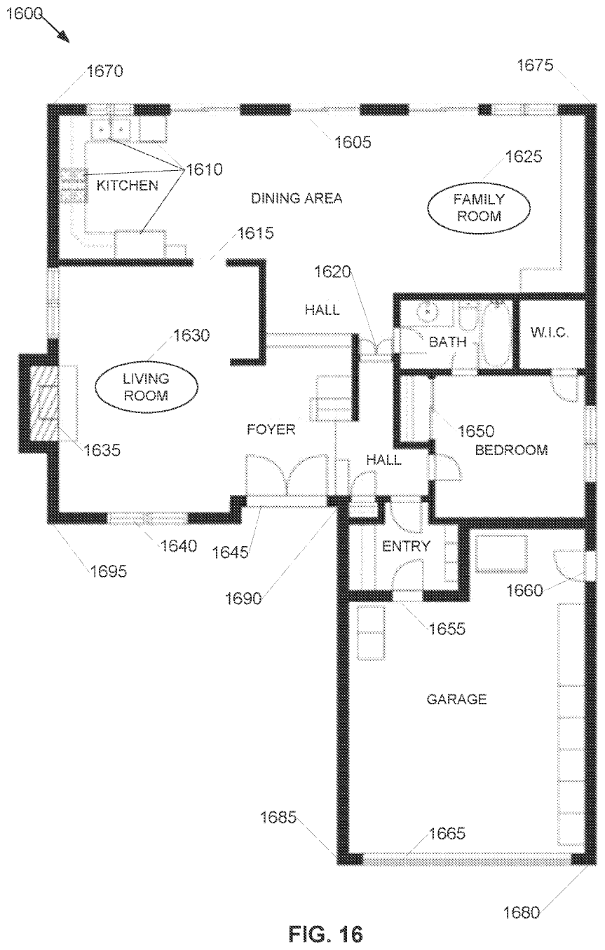

FIG. 16 is a block diagram illustrating an example property level layer 1600 according to an embodiment of the invention. In the illustrated embodiment, the structural footprint layer 1600 includes a plurality of anchors. Although all of the anchors are not labeled, the anchors include semi-permanent parts of the physical structure of the property such as sliding doors 1605, appliances 1610 such as the refrigerator, dishwasher, sink, oven, etc., internal passageways 1615, fireplaces 1635, windows 1640, external doorways 1645 and 1660, closets 1650, and doorways between rooms 1620 and 1655, and garage doors 1665. The property level layer 1600 also includes room identifiers such as identifier 1625 for the family room and identifier 1630 for the living room.

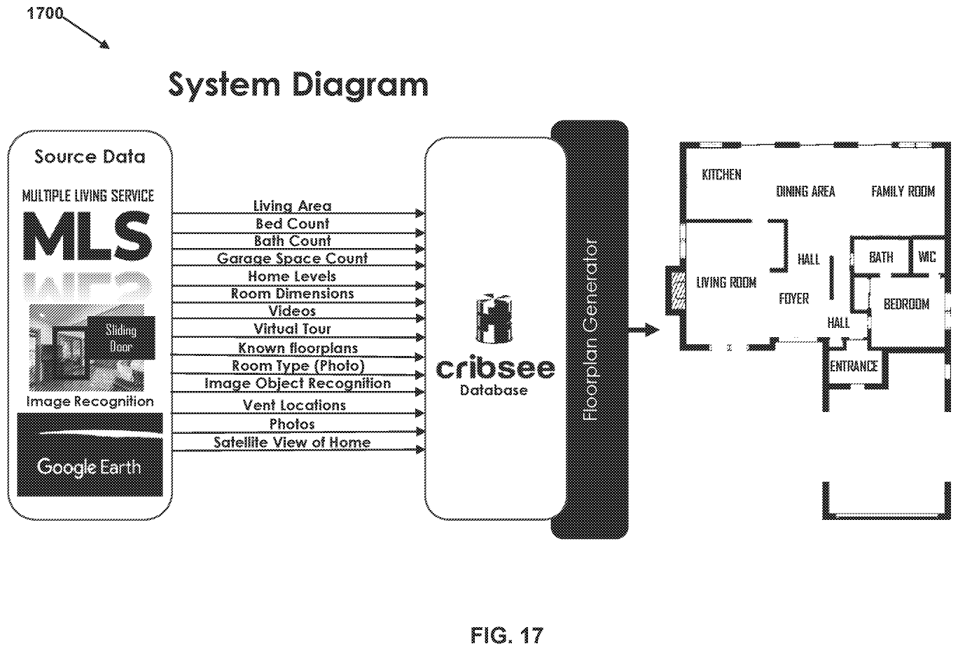

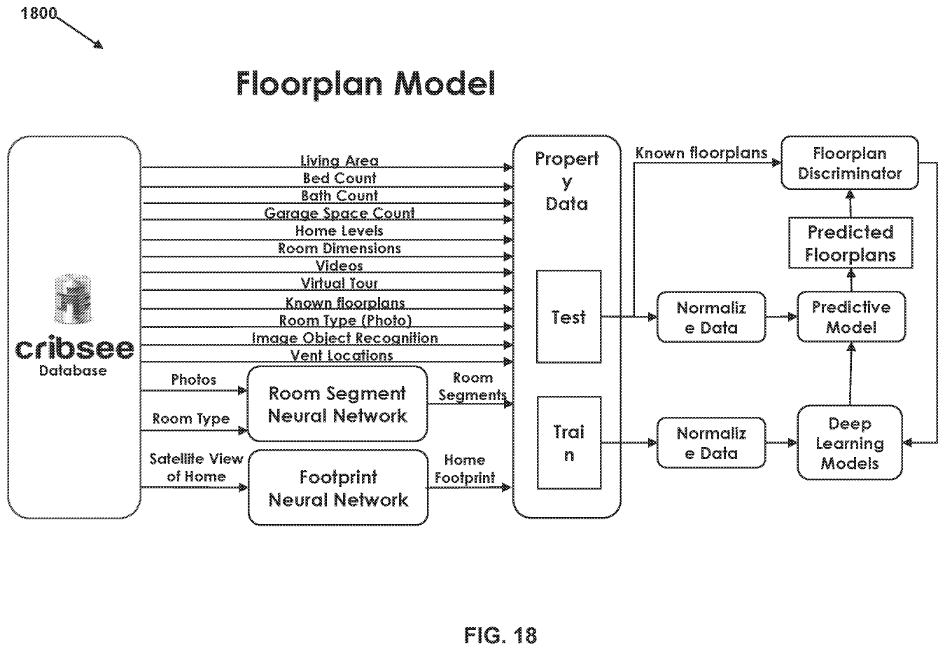

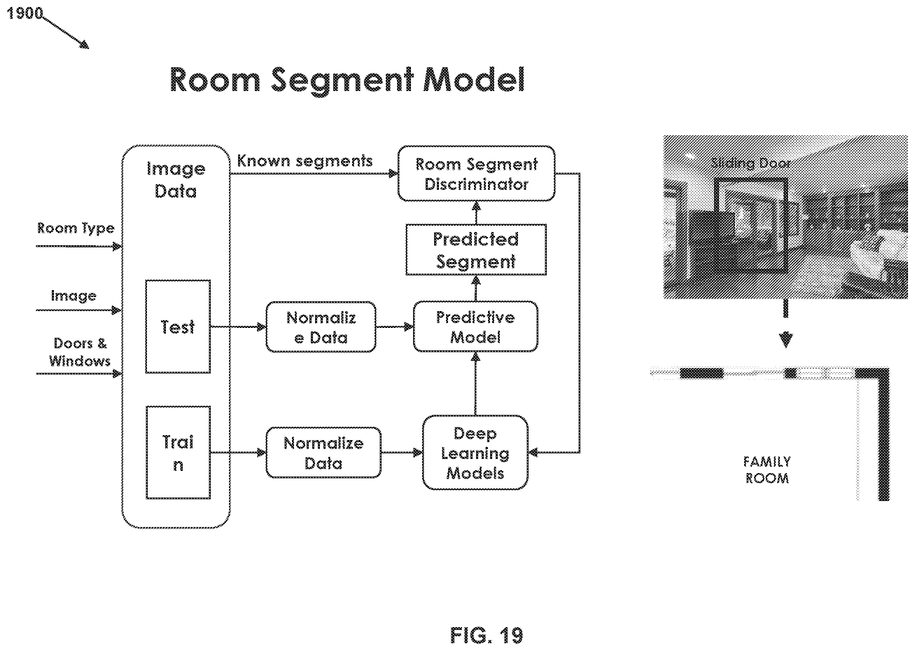

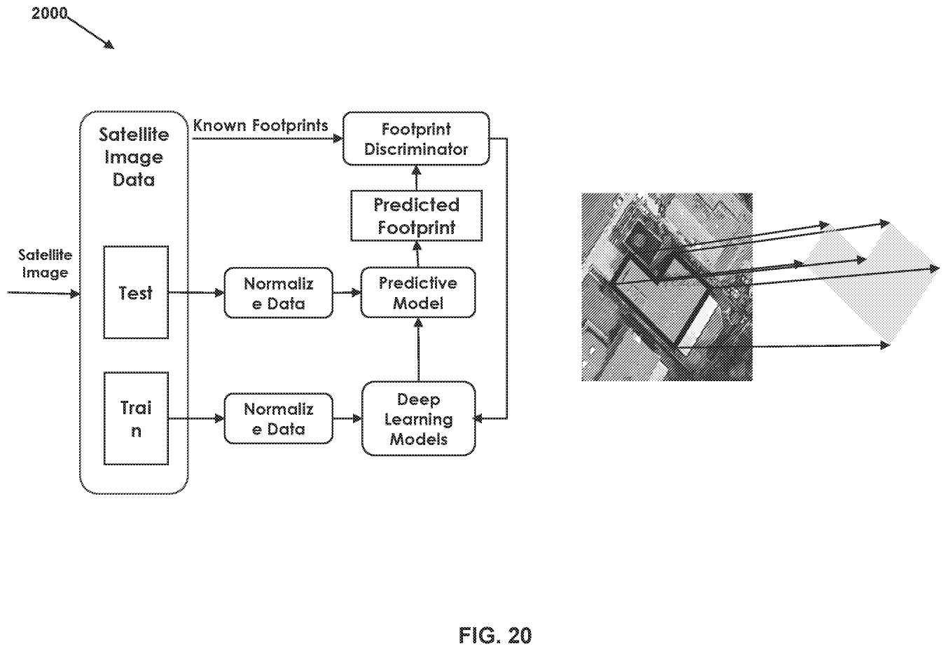

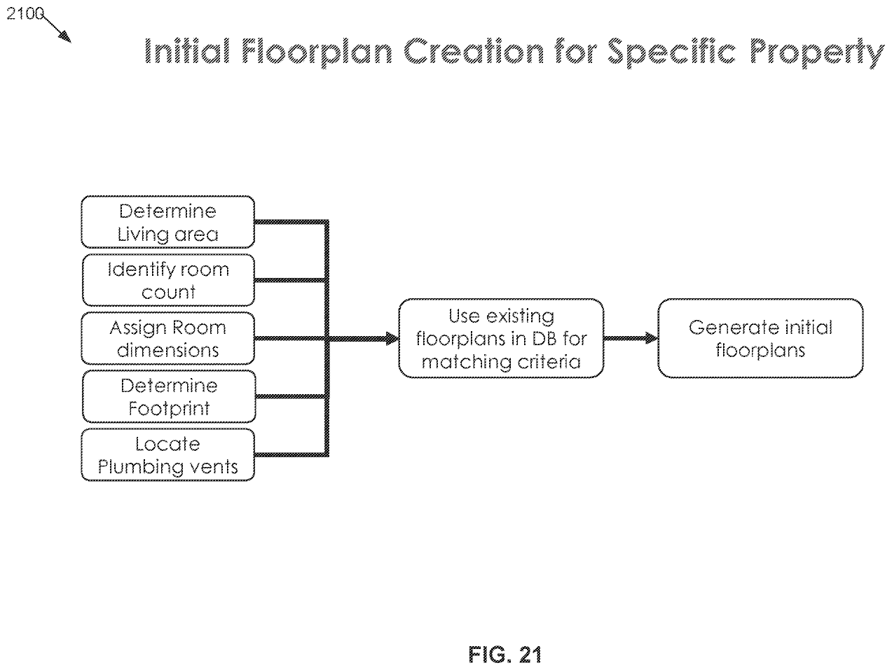

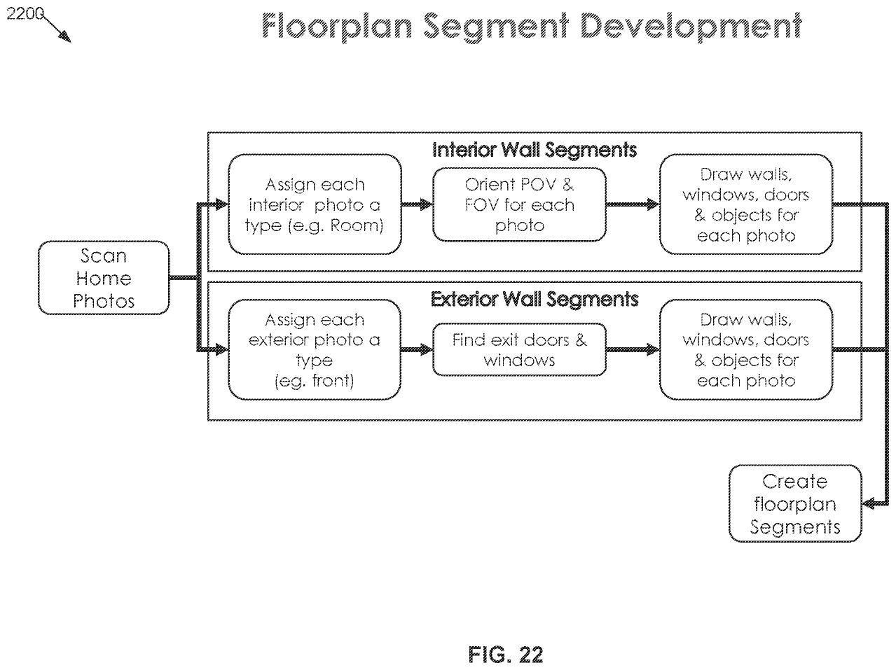

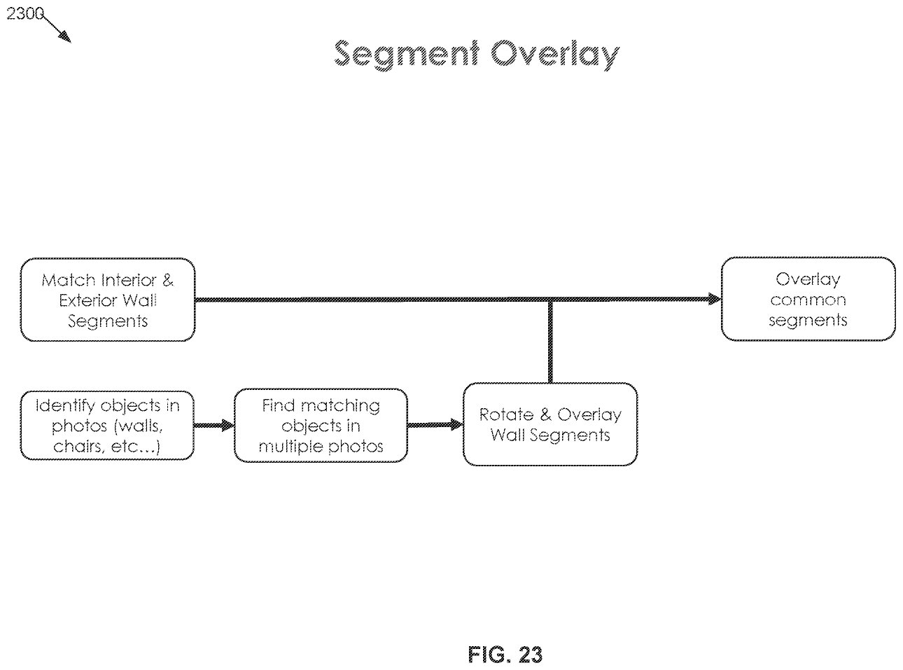

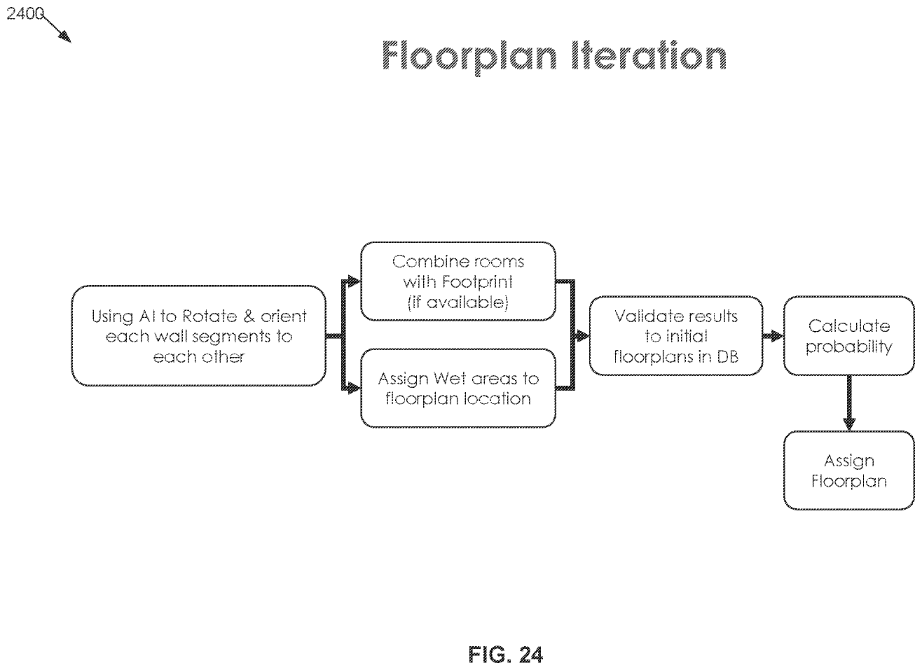

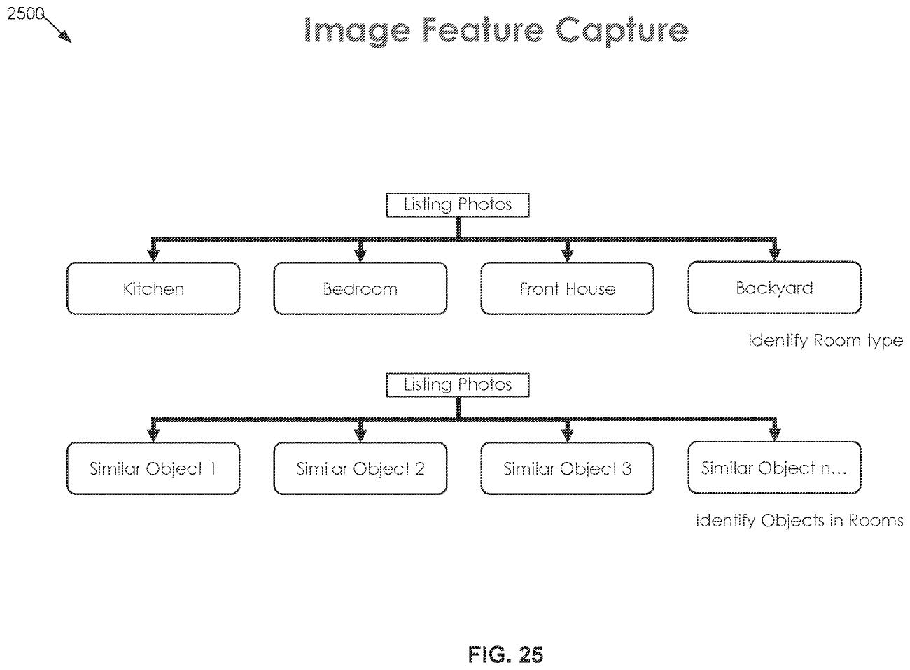

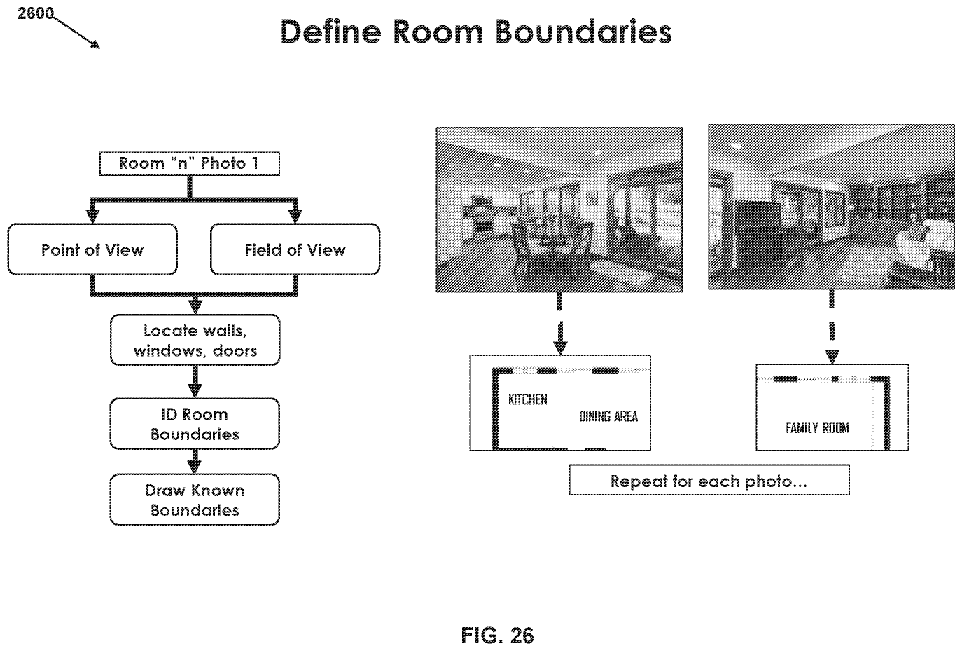

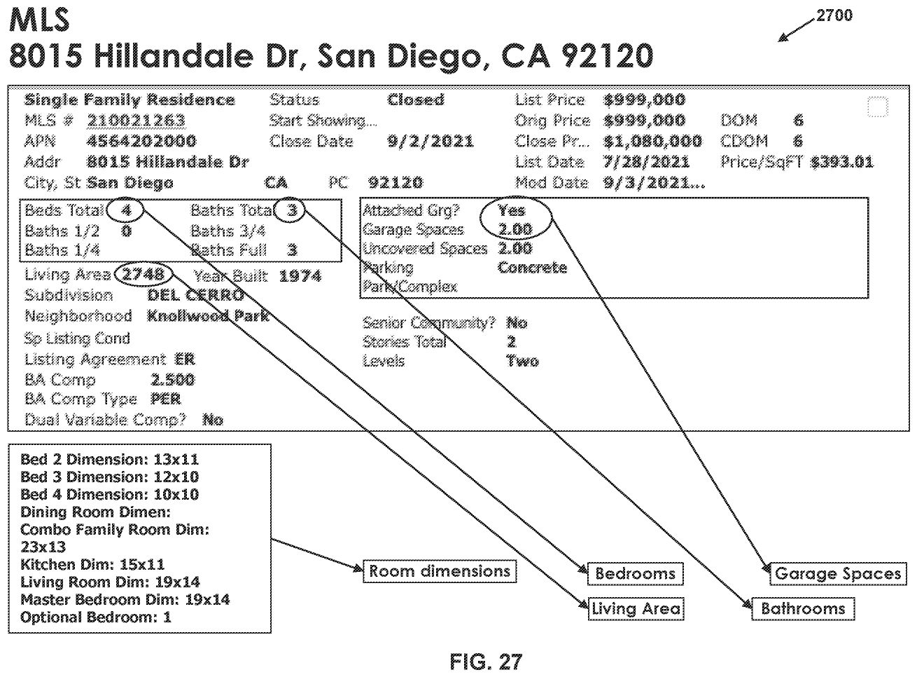

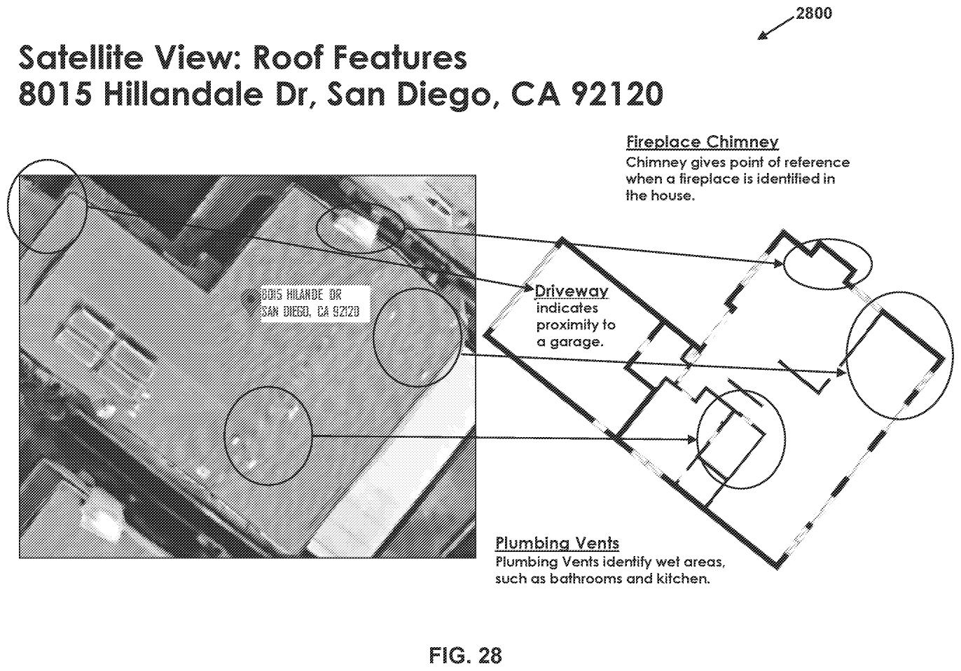

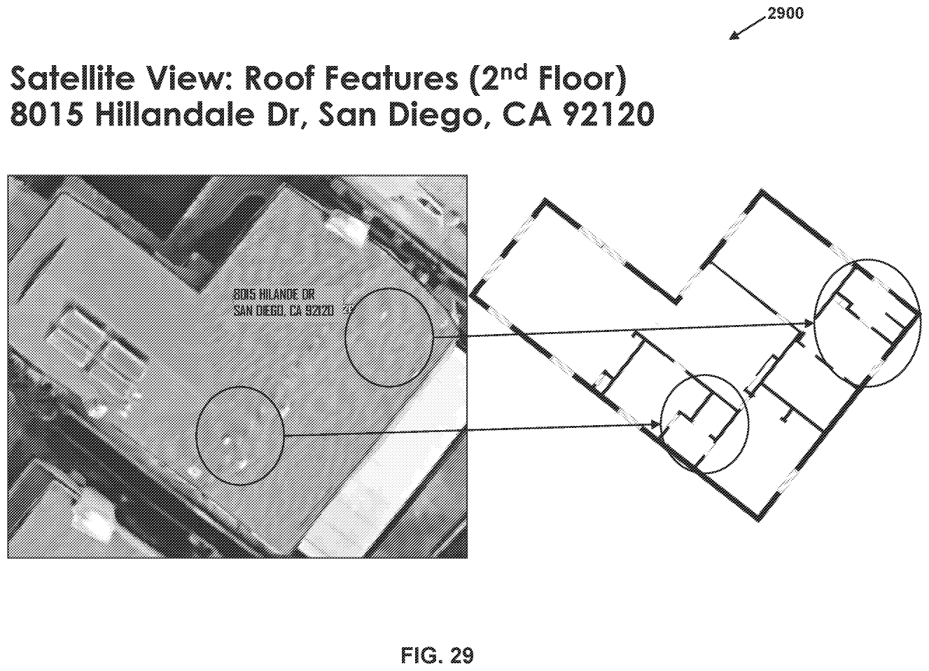

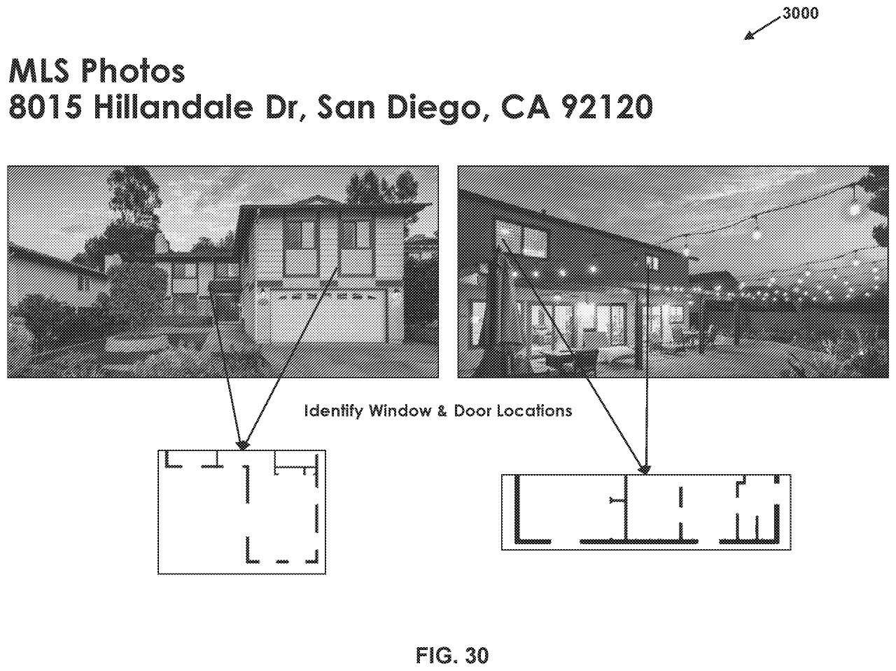

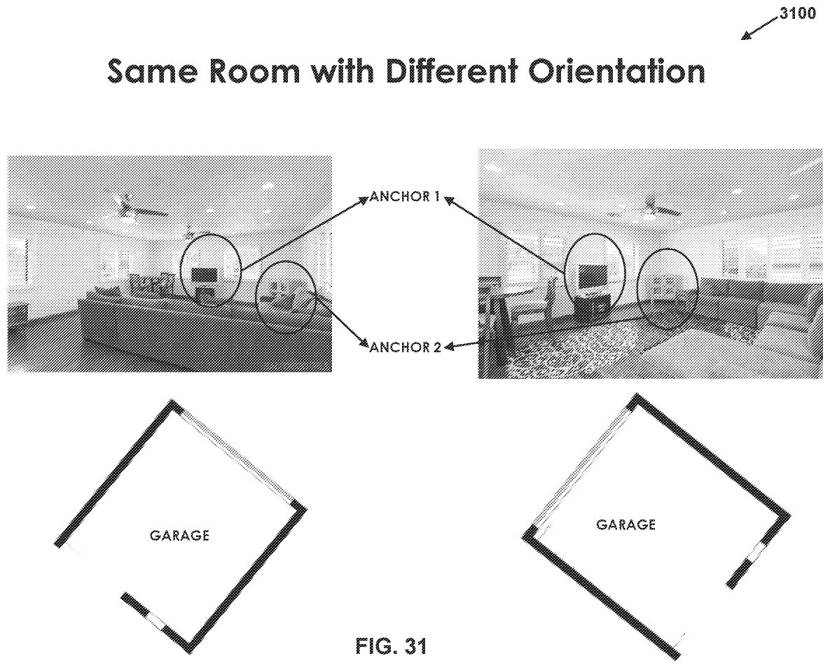

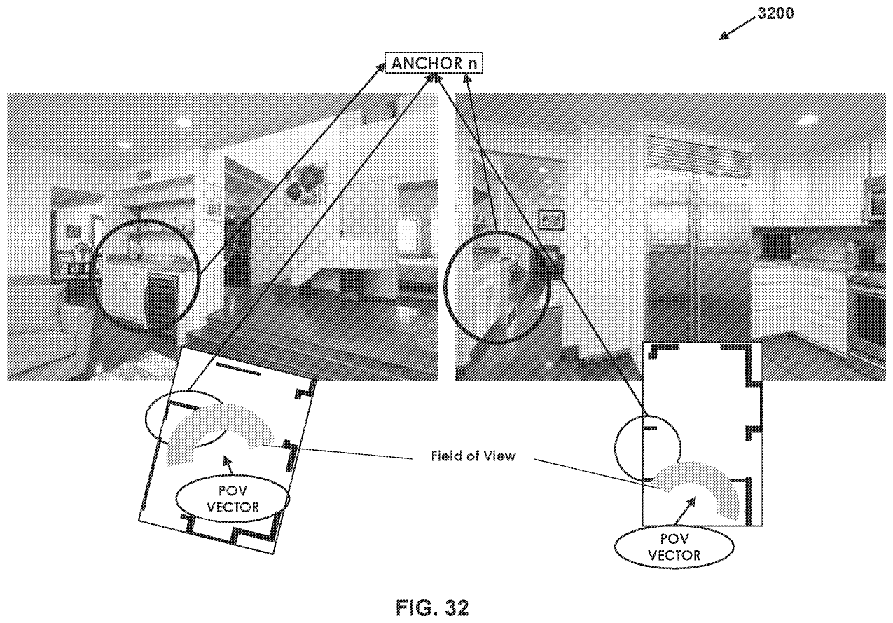

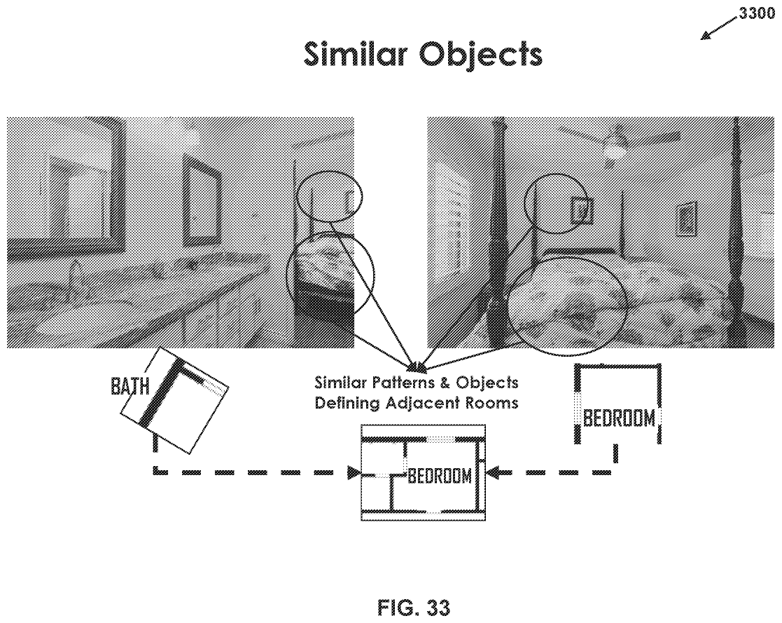

FIG. 17-33 are block diagrams illustrating an example system implementation according to an embodiment of the invention.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly not limited.

What is claimed is:

1. A computer implemented method for generating an estimated floorplan of a physical structure, where one or more processors are programmed to perform steps comprising:
obtaining property data corresponding to a property, the property data including one or more of location, living area, bedroom count, bathroom count, garage count, number of levels, room dimensions, key anchors, and key objects;
obtaining digital media of the property including one or more of satellite images, photographic images, videos, virtual tours, and other digital representations of the property;
analyzing the digital media to determine a structural footprint for the property, wherein the structural footprint defines a first layer of an overall floorplan estimate;
analyzing the digital media to determine a number of structural segments for the property;
identifying key anchors and key objects that are common to one or more structural segments;
aligning a first set of two or more structural segments using the key anchors and key objects that are common to each of the two or more structural segments in the first set to generate a first portion of a floor plan of a first level of the property;
aligning a second set of two or more structural segments using the key anchors and key objects that are common to each of the two or more structural segments in the second set to generate a second portion of the floor plan of the first level of the property;
combining the first portion and the second portion into an estimated floor plan of the first level of the property, wherein the estimated floor plan of the first level of the property defines a second layer of the overall floorplan estimate; and
aligning the first layer of the overall floorplan estimate with the second layer of the overall floorplan estimate to generate an overall floorplan estimate of the property.

2. The method of claim 1, further comprising:
aligning additional sets of two or more structural segments using the key anchors and key objects that are common to each respective additional set of two or more structural segments to generate an estimated floor plan of a second level of the property, wherein the estimated floor plan of the second level of the property defines a third layer of the overall floorplan estimate,
wherein aligning comprises aligning the first layer, the second layer, and the third layer to generate the overall floorplan estimate of the property.

3. The method of claim 2, further comprising storing the overall floorplan estimate of the property in a data storage area.

4. The method of claim 2, further comprising requesting validation of the overall floorplan estimate from an owner of the property or a real estate agent/broker.

5. The method of claim 1, wherein key anchors comprise one or more of a chimney, skylight, plumbing vents, fireplace, doors, windows, driveway, swimming pool, hot tub, microwave, stove, sink, and refrigerator.

6. The method of claim 1, wherein key objects comprise one or more of vehicles, televisions, furniture, and art.

7. A system for generating an estimated floorplan of a physical structure, comprising:
means for obtaining property data corresponding to a property, the property data including one or more of location, living area, bedroom count, bathroom count, garage count, number of levels, room dimensions, key anchors, and key objects;
means for obtaining digital media of the property including one or more of satellite images, photographic images, videos, virtual tours, and other digital representations of the property;
means for analyzing the digital media to determine a structural footprint for the property, wherein the structural footprint defines a first layer of an overall floorplan estimate;
means for analyzing the digital media to determine a number of structural segments for the property;
means for identifying key anchors and key objects that are common to one or more structural segments;
means for aligning a first set of two or more structural segments using the key anchors and key objects that are common to each of the two or more structural segments in the first set to generate a first portion of a floor plan of a first level of the property;
means for aligning a second set of two or more structural segments using the key anchors and key objects that are common to each of the two or more structural segments in the second set to generate a second portion of the floor plan of the first level of the property;
means for combining the first portion and the second portion into an estimated floor plan of the first level of the property, wherein the estimated floor plan of the first level of the property defines a second layer of the overall floorplan estimate; and
means for aligning the first layer of the overall floorplan estimate with the second layer of the overall floorplan estimate to generate an overall floorplan estimate of the property.

8. The system of claim 7, further comprising:
means for aligning additional sets of two or more structural segments using the key anchors and key objects that are common to each respective additional set of two or more structural segments to generate an estimated floor plan of a second level of the property, wherein the estimated floor plan of the second level of the property defines a third layer of the overall floorplan estimate,
wherein the means for aligning the first layer is configured to align the first layer, the second layer, and the third layer to generate the overall floorplan estimate for the property.

9. The system of claim 8, further comprising storing the overall floorplan estimate for the property in a data storage area.

10. The system of claim 8, further comprising requesting validation of the overall floorplan estimate for the property from an owner of the property or a real estate agent/broker.

11. The system of claim 7, wherein key anchors comprise one or more of a chimney, skylight, plumbing vents, fireplace, doors, windows, driveway, swimming pool, hot tub, microwave, stove, sink, and refrigerator.

12. The system of claim 7, wherein key objects comprise one or more of vehicles, televisions, furniture, and art.
